(19) United States
(12) Patent Application Publication
(10) Pub. No.: US 2026/0102867 A1
(43) Pub. Date: Apr. 16, 2026

(54) WAFER PROCESSING METHOD AND GRINDING APPARATUS

(71) Applicant: DISCO CORPORATION, Tokyo (JP)

(72) Inventors: Akira MIZUTANI, Tokyo (JP); Taku IWAMOTO, Tokyo (JP); Satoru FUJIMURA, Tokyo (JP); Takeshi UENO, Tokyo (JP)

(21) Appl. No.: 19/349,066

(22) Filed: Oct. 3, 2025

(30) Foreign Application Priority Data
Oct. 15, 2024 (JP) 2024-179964

(51) Int. Cl. B24B 7/22; B24B 41/06; H01L 21/304

(52) U.S. Cl. CPC B24B 7/228; B24B 41/068; H10P 52/00

(57) ABSTRACT

A wafer processing method includes forming a ring-shaped modified layer by holding a second wafer of a bonded wafer on a holding table and applying a laser beam with a focal point of the laser beam positioned on an inner side adjacent to a chamfered portion formed at an outer periphery of a first wafer of the bonded wafer; loading the bonded wafer onto a grinding apparatus for grinding the first wafer of the bonded wafer; and grinding the first wafer to thin the first wafer and remove the chamfered portion formed at the outer periphery of the first wafer by a grinding force. The loading or the grinding includes supplying a fluid for weakening a bonding force to an interface of the chamfered portion at which the first wafer and the second wafer are bonded.

### BACKGROUND

### 1. TECHNICAL FIELD

The present disclosure relates to a wafer processing method for processing a first wafer of a bonded wafer in which the first wafer and a second wafer are bonded, and a grinding apparatus that grinds a first wafer of a bonded wafer in which the first wafer and a second wafer are bonded.

### 2. DESCRIPTION OF THE RELATED ART

A wafer having multiple devices such as ICs and LSIs, which are formed on a surface and defined by division lines, is ground at its back surface to a predetermined thickness, and is then divided into individual device chips using a dicing apparatus and a laser processing apparatus. The divided device chips are used in electrical devices such as mobile phones and personal computers.

A chamfered portion is formed at the outer periphery of the wafer when the wafer is thinned by grinding at its back surface, and the chamfered portion forms a sharp knife edge. This increases the likelihood of a crack extending from the outer periphery of the wafer to the inner side, increasing the risk of device damage. Also, the chamfered portion forming a sharp knife edge requires the operator to be more careful when handling the wafer. In this respect, the present applicant has proposed a technique for removing the chamfered portion (see, for example, JP 2020-88187 A).

### SUMMARY

There is a technique in which a first wafer is bonded to a second wafer to improve the function of devices, and then the back surface of the first wafer is ground to a desired thickness. However, an issue with this technique is that it is relatively difficult to remove the chamfered portion from the first wafer. That is, a wafer bonded by siloxane bonding or the like has a strong bonding force, and even if a laser beam having a wavelength transmittable through the wafer is applied with the focal point of the laser beam positioned on the inner side adjacent to the chamfered portion to form a modified layer inside the first wafer, it is still difficult to remove the chamfered portion.

Also, when a cutting blade is used to remove the chamfered portion from the first wafer, the second wafer may be scratched.

An object of the present disclosure is to provide a wafer processing method and grinding apparatus capable of easily removing a chamfered portion of a first wafer from a bonded wafer in which the first wafer and a second wafer are bonded.

According to the present disclosure, the following wafer processing method that solves the above issues is provided. That is,

"A wafer processing method for processing a first wafer of a bonded wafer in which the first wafer and a second wafer are bonded, the wafer processing method including:

forming a ring-shaped modified layer by holding the second wafer of the bonded wafer on a holding table and applying a laser beam with a focal point of the laser beam positioned on an inner side adjacent to a chamfered portion formed at an outer periphery of the first wafer of the bonded wafer;

loading the bonded wafer onto a grinding apparatus for grinding the first wafer of the bonded wafer; and

grinding the first wafer to thin the first wafer and remove the chamfered portion formed at the outer periphery of the first wafer by a grinding force, in which

the loading or the grinding includes supplying a fluid for weakening a bonding force to an interface of the chamfered portion at which the first wafer and the second wafer are bonded" is provided.

Preferably, the supplying the fluid uses a fluid supply nozzle having a tip for injecting the fluid. The fluid is preferably water. The first wafer and the second wafer are bonded by Si-O-Si siloxane bonding, and the supplying the fluid includes the fluid for weakening the bonding force converting Si-O-Si bonding into Si-OH-OH-Si bonding to weaken the bonding force.

Furthermore, according to the present disclosure, the following grinding apparatus for solving the above issues is provided. That is,

"A grinding apparatus for grinding a first wafer of a bonded wafer in which the first wafer and a second wafer are bonded, the grinding apparatus including:

a chuck table configured to hold the bonded wafer; a grinding unit including a grinding wheel that is rotationally attached and includes grindstones arranged annularly to grind the first wafer of the bonded wafer held by the chuck table; and a fluid supply unit configured to supply a fluid for weakening a bonding force to an interface of a chamfered portion at which the first wafer and the second wafer are bonded" is provided.

A cassette table on which a cassette containing a plurality of the bonded wafers is to be placed, a transport unit configured to unload the bonded wafer from the cassette placed on the cassette table and transport the bonded wafer to a temporary receiving table at which centering is performed, a loading unit configured to load the bonded wafer onto the chuck table positioned at a loading and unloading region from the temporary receiving table, and a moving unit configured to move the chuck table from the loading and unloading region to a processing region at which the grinding unit grinds the first wafer are preferably included. The fluid supply unit is preferably located at the loading and unloading region or the processing region. The fluid may be water. The first wafer and the second wafer are bonded by Si-O-Si siloxane bonding, and the fluid for weakening the bonding force converts Si-O-Si bonding into Si-OH-OH-Si bonding to weaken the bonding force.

The wafer processing method of the present disclosure is

a wafer processing method for processing a first wafer of a bonded wafer in which the first wafer and a second wafer are bonded, the wafer processing method including:

forming a ring-shaped modified layer by holding the second wafer of the bonded wafer on a holding table and applying a laser beam with a focal point of the laser beam positioned on an inner side adjacent to a chamfered portion formed at an outer periphery of the first wafer of the bonded wafer;

loading the bonded wafer onto a grinding apparatus for grinding the first wafer of the bonded wafer; and

grinding the first wafer to thin the first wafer and remove the chamfered portion formed at the outer periphery of the first wafer by a grinding force, in which

the loading or the grinding includes supplying a fluid for weakening a bonding force to an interface of the chamfered portion at which the first wafer and the second wafer are bonded. As such, the chamfered portion of the first wafer can be easily removed from the bonded wafer in which the first wafer and the second wafer are bonded.

The grinding apparatus of the present disclosure is

a grinding apparatus for grinding a first wafer of a bonded wafer in which the first wafer and a second wafer are bonded, the grinding apparatus including:

a chuck table configured to hold the bonded wafer; a grinding unit including a grinding wheel that is rotationally attached and includes grindstones arranged annularly to grind the first wafer of the bonded wafer held by the chuck table; and a fluid supply unit configured to supply a fluid for weakening a bonding force to an interface of a chamfered portion at which the first wafer and the second wafer are bonded. Thus, the grinding apparatus is capable of removing a chamfered portion of the first wafer from the bonded wafer in which the first wafer and the second wafer are bonded.

### BRIEF DESCRIPTION OF THE DRAWINGS

FIG. 1 is a perspective view of a grinding apparatus according to a present disclosure;

FIG. 2A is a perspective view of a bonded wafer;

FIG. 2B is a partial cross-sectional view of the bonded wafer shown in FIG. 2A;

FIG. 3A is a perspective view showing forming of a modified layer;

FIG. 3B is a partial cross-sectional view of a bonded wafer in which a ring-shaped modified layer is formed in the first wafer;

FIG. 4 is a plan view of a wafer in which radial modified layers extending radially outward from a ring-shaped modified layer are formed;

FIG. 5A is a perspective view showing fluid supplying;

FIG. 5B is a partial cross-sectional view of a bonded wafer with a fluid supplied to the interface of the chamfered portions;

FIG. 6A is a perspective view showing rough grinding in grinding;

FIG. 6B is a perspective view of a bonded wafer from which the chamfered portion of the first wafer is removed;

FIG. 7A is a perspective view showing finish grinding in grinding; and

FIG. 7B is a perspective view of a bonded wafer in which the back surface of the first wafer is finish-ground.

### DESCRIPTION OF THE PREFERRED EMBODIMENTS

Hereinafter, preferred embodiments of a wafer processing method and a grinding apparatus according to the present disclosure will be described in detail with reference to the drawings.

### Grinding Apparatus 2

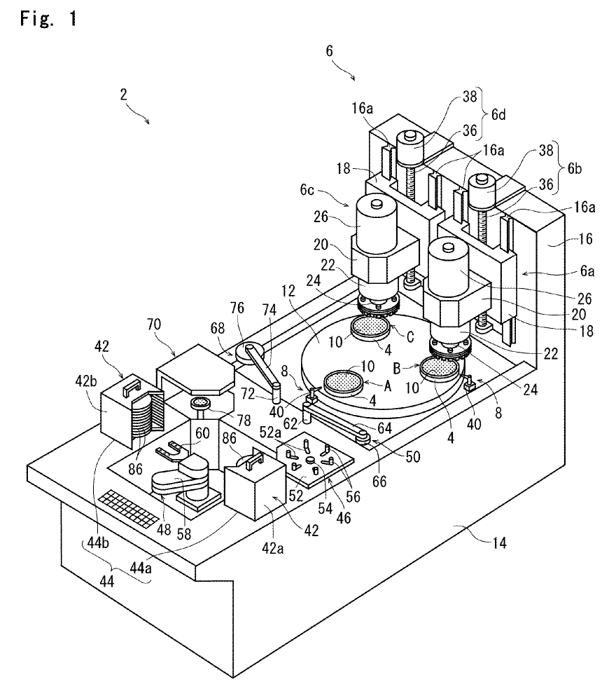

As shown in FIG. 1, a grinding apparatus 2 of the present embodiment includes chuck tables 4, which hold bonded wafers, a grinding unit 6 including a grinding wheel that is rotationally attached and includes grindstones arranged annularly to grind a first wafer of the bonded wafer held by the chuck table 4, and a fluid supply unit 8 that supplies a fluid for weakening a bonding force to an interface of a chamfered portion at which a first wafer and a second wafer are bonded.

### Chuck Table 4 of Grinding Apparatus 2

A circular suction chuck 10 is placed on the upper end of each chuck table 4. The suction chuck 10 is made of a porous material such as porous ceramics. The suction chuck 10 is connected to a suction unit (not shown). The chuck table 4 generates a suction force at the upper surface of the suction chuck 10 using the suction unit, and holds a bonded wafer by suction on the upper surface of the suction chuck 10. The chuck table 4 is rotated by a chuck table motor (not shown) about an axis extending in the up-down direction.

The grinding apparatus 2 of this embodiment includes three chuck tables 4. The three chuck tables 4 are attached to the upper surface of a circular turntable 12 at equal intervals in the circumferential direction. The turntable 12 is rotationally supported on the upper surface of a base 14 of the grinding apparatus 2. The turntable 12 rotates to position the three chuck tables 4 at a loading and unloading region A, a rough processing region B, and a finish processing region C in turn.

### Grinding Unit 6 of Grinding Apparatus 2

The grinding unit 6 includes a first grinding unit 6a, which roughly grinds the bonded wafer positioned at the rough processing region B, a first grinding feed unit 6b, which feeds the first grinding unit 6a for grinding, a second grinding unit 6c, which finish-grinds the bonded wafer positioned at the finish processing region C, and a second grinding feed unit 6d, which feeds the second grinding unit 6c for grinding.

### First Grinding Unit 6a of Grinding Unit 6

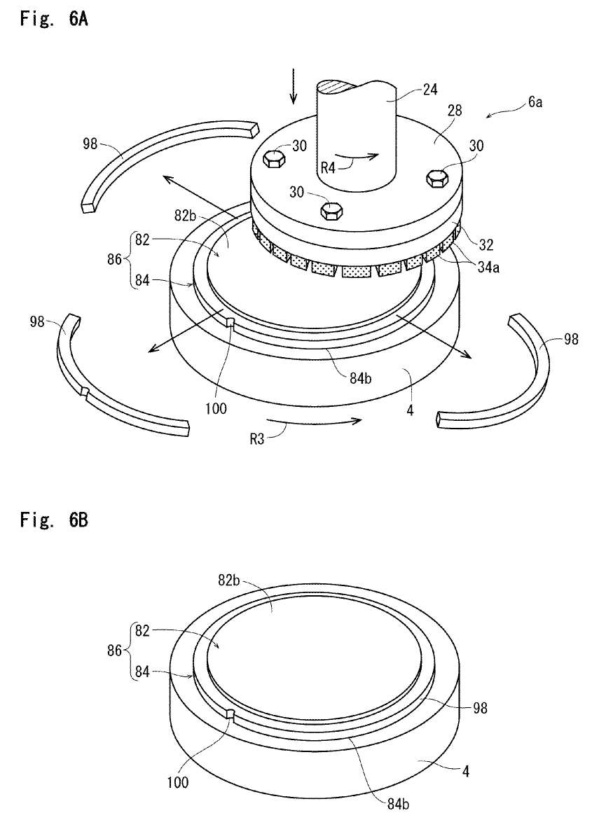

The first grinding unit 6a has an elevating plate 18 supported on a support wall 16, which extends upward from an end portion (the rear end portion as viewed in FIG. 1) of the base 14, so as to be movable in the up-down direction, a protruding member 20 extending from the elevating plate 18, a spindle housing 22 attached to the protruding member 20, a spindle 24 rotationally supported by the spindle housing 22, and a motor 26 for rotating the spindle 24. As shown in FIG. 6A, a disk-shaped wheel mount 28 is fixed to the lower end of the spindle 24. An annular grinding wheel 32 is fastened to the lower surface of the wheel mount 28 by bolts 30. Multiple grindstones 34a for rough grinding are fixed to the lower surface of the grinding wheel 32 and are arranged annularly at intervals in the circumferential direction.

### First Grinding Feed Unit 6b of Grinding Unit 6

As shown in FIG. 1, the first grinding feed unit 6b includes a ball screw 36, which extends in the up-down direction along one surface of the support wall 16, and a motor 38 for rotating the ball screw 36. The nut portion (not shown) of the ball screw 36 is coupled to the elevating plate 18. The first grinding feed unit 6b converts the rotational motion of the motor 38 into linear motion using the ball screw 36 and transmits it to the elevating plate 18, thereby feeding the first grinding unit 6a for grinding in the up-down direction along a guide rail 16a of the support wall 16.

### Second Grinding Unit 6c of Grinding Unit 6

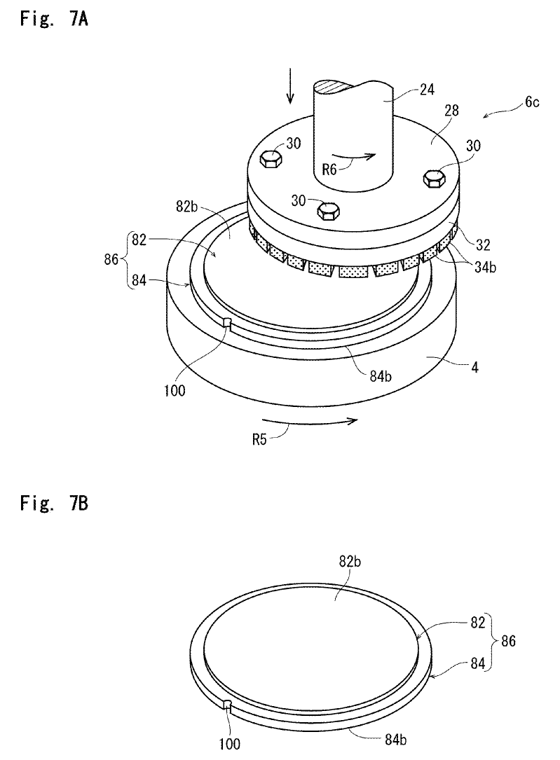

The second grinding unit 6c performs finish grinding on the bonded wafer. The grindstones 34b of the second grinding unit 6c (see FIG. 7A) are grindstones for finish grinding, and are made of abrasive grains smaller than the abrasive grains of the grindstones 34a of the first grinding unit 6a (grindstones for rough grinding). The second grinding unit 6c may have the same configuration as the first grinding unit 6a except for the grindstones 34b, so the same reference numerals as those in the first grinding unit 6a are used, and the description thereof is omitted.

### Second Grinding Feed Unit 6d of Grinding Unit 6

The second grinding feed unit 6d feeds the second grinding unit 6c for grinding in the up-down direction. The second grinding feed unit 6d may have the same configuration as the first grinding feed unit 6b, so the same reference numerals as those in the first grinding feed unit 6b are used, and the description thereof is omitted.

### Fluid Supply Unit 8 of Grinding Apparatus 2

The fluid supply unit 8 includes a fluid supply source (not shown) and a fluid supply nozzle 40 having a tip for injecting a fluid (e.g., pure water) supplied from the fluid supply source. As shown in FIG. 1, in this embodiment, the fluid supply nozzle 40 is provided at both the loading and unloading region A and the rough processing region B, but it may be provided at one of the loading and unloading region A and the rough processing region B. Also, the fluid supplied by the fluid supply unit 8 is not limited to a liquid form, and may be a vapor or mist form.

Also, the fluid supply unit 8 may be configured to supply a fluid for weakening a bonding force to the interface of the chamfered portion by submerging the bonded wafer in a water tank (not shown) containing a fluid. The water tank of the fluid supply unit 8 can be installed around a cassette table 44 or a temporary receiving table 46, which is described below, so as to be movable in the up-down direction. When the water tank is installed around the cassette table 44, after a cassette 42 described below is placed on the cassette table 44, the water tank is positioned at an operating position where it can store fluid. Then, the fluid is stored inside the water tank so that the bonded wafers in the cassette 42 are submerged. The fluid is thus supplied to the interface of the chamfered portion. Also, when the water tank is installed around the temporary receiving table 46, after the bonded wafer is placed on the temporary receiving table 46, the water tank is positioned at an operating position where it can store fluid. Then, the fluid is stored inside the water tank so that the bonded wafer on the temporary receiving table 46 is submerged. The fluid is thus supplied to the interface of the chamfered portion.

As shown in FIG. 1, the grinding apparatus 2 of this embodiment further includes a cassette table 44, on which a cassette 42 containing multiple bonded wafers is placed, a transport unit 48, which unloads a bonded wafer from the cassette 42 placed on the cassette table 44 and transports it to the temporary receiving table 46 for centering, a loading unit 50, which loads the bonded wafer onto the chuck table 4 positioned at the loading and unloading region A from the temporary receiving table 46, and a moving unit, which is configured like a turntable and moves the chuck table 4 from the loading and unloading region A to a processing region to grind the first wafer with the grinding unit 6.

### Cassette Table 44 of Grinding Apparatus 2

The cassette table 44 includes a first cassette table 44a, on which a first cassette 42a containing bonded wafers before grinding is placed, and a second cassette table 44b, on which a second cassette 42b containing bonded wafers after grinding is placed.

### Temporary Receiving Table 46 of Grinding Apparatus 2

The temporary receiving table 46 includes a base plate 52, which is supported on the upper surface of the base 14, and a circular support base 54, which is placed in the center of the upper surface of the base plate 52 and has a smaller diameter than the bonded wafer. The base plate 52 has multiple elongated holes 52a that extend in the radial direction of the support base 54 and are formed at intervals around the circumference of the support base 54. Multiple movable pins 56 extend upward in the elongated holes 52a. Also, a pin moving unit (not shown) for synchronously moving the multiple pins 56 along the elongated holes 52a is attached to the base plate 52. The temporary receiving table 46 synchronously moves the multiple pins 56 using the pin moving unit so that the pins 56 abut against the outer periphery of the bonded wafer placed on the support base 54, thereby aligning the center of the bonded wafer with the center of the support base 54.

### Transport Unit 48 of Grinding Apparatus 2

The transport unit 48 includes a multi-joint arm 58, which is supported on the base 14, an actuator (not shown) for operating the multi-joint arm 58, and a holding piece 60, which is attached to the tip of the multi-joint arm 58. One surface of the holding piece 60 has multiple suction holes (reference number omitted). Each suction hole is connected to a suction unit (not shown). The transport unit 48 generates a suction force at the suction holes of the holding piece 60 using the suction unit, and holds the bonded wafer by suction on one surface of the holding piece 60. The transport unit 48 also operates the multi-joint arm 58 with the actuator to transport the bonded wafer before grinding from the first cassette 42a to the temporary receiving table 46, and transports the bonded wafer after grinding from a cleaning unit 70, which will be described below, to the second cassette 42b.

### Loading Unit 50 of Grinding Apparatus 2

The loading unit 50 includes a rotation shaft 62, which is attached to the the base 14 so as to be rotatable and movable in the up-down direction, an arm 64, which extends substantially horizontally from the upper end of the rotation shaft 62, a suction piece 66, which is attached to the lower surface of the tip of the arm 64, a rotation shaft motor (not shown) for rotating the rotation shaft 62, and an elevating unit (not shown) such as an air cylinder for lifting and lowering the rotation shaft 62. The lower surface of the suction piece 66 has multiple suction holes (not shown). Each suction hole is connected to a suction unit (not shown). The loading unit 50 generates a suction force at the suction holes of the suction piece 66 using the suction unit, and holds the bonded wafer by suction on the temporary receiving table 46 using the suction piece 66. The loading unit 50 also lifts, lowers, and rotates the rotation shaft 62 using the lifting unit and the rotation shaft motor to load the bonded wafer onto the chuck table 4 positioned at the loading and unloading region A from the temporary receiving table 46.

### Moving Unit of Grinding Apparatus 2

The moving unit of the present embodiment includes the turntable 12 described above and a turntable motor (not shown) for rotating the turntable 12. The moving unit rotates the turntable 12 to move the chuck table 4 to the loading and unloading region A, the rough processing region B, and the finish processing region C in turn. The moving unit is not limited to the above form. For example, when one of each of the chuck table 4 and the grinding unit and the grinding feed unit of the grinding unit 6 is provided, the moving unit may be a ball screw type moving unit for moving the chuck table 4 linearly to the loading and unloading region and the processing region.

The grinding apparatus 2 further includes an unloading unit 68, which unloads the bonded wafer after grinding from the chuck table 4 positioned at the loading and unloading region A, and a cleaning unit 70, which cleans the unloaded bonded wafer after grinding.

### Unloading Unit 68 of Grinding Apparatus 2

The unloading unit 68 includes a rotation shaft 72, which is attached to the base 14 so as to be rotatable and movable in the up-down direction, and an arm 74, which extends substantially horizontally from the upper end of the rotation shaft 72, a suction piece 76, which is attached to the lower surface of the tip of the arm 74, a rotation shaft motor (not shown) for rotating the rotation shaft 72, and an elevating unit (not shown) such as an air cylinder for lifting and lowering the rotation shaft 72. The lower surface of the suction piece 76 has multiple suction holes (not shown). Each suction hole is connected to a suction unit (not shown). The unloading unit 68 generates a suction force at the suction holes of the suction pieces 76 using the suction unit, and holds the bonded wafer after grinding by suction on the chuck table 4 positioned at the loading and unloading region A using the suction piece 76. The unloading unit 68 also lifts, lowers, and rotates the rotation shaft 72 using the elevating unit and the rotation shaft motor to unload the bonded wafer after grinding from the chuck table 4 positioned at the loading and unloading region A.

### Cleaning Unit 70 of Grinding Apparatus 2

The cleaning unit 70 includes a spinner table 78, which holds the bonded wafer by suction, a spinner table motor (not shown) for rotating the spinner table 78, a cleaning water nozzle (not shown) for injecting cleaning water onto the bonded wafer held by suction on the spinner table 78, and an air nozzle (not shown) for injecting dry air onto the bonded wafer held by suction on the spinner table 78. While rotating the spinner table 78 holding the bonded wafer by suction, the cleaning unit 70 cleans the bonded wafer by injecting cleaning water from the cleaning water nozzle and, after the cleaning with cleaning water, dries the bonded wafer by injecting dry air from the air nozzle.

### Bonded Wafer 86

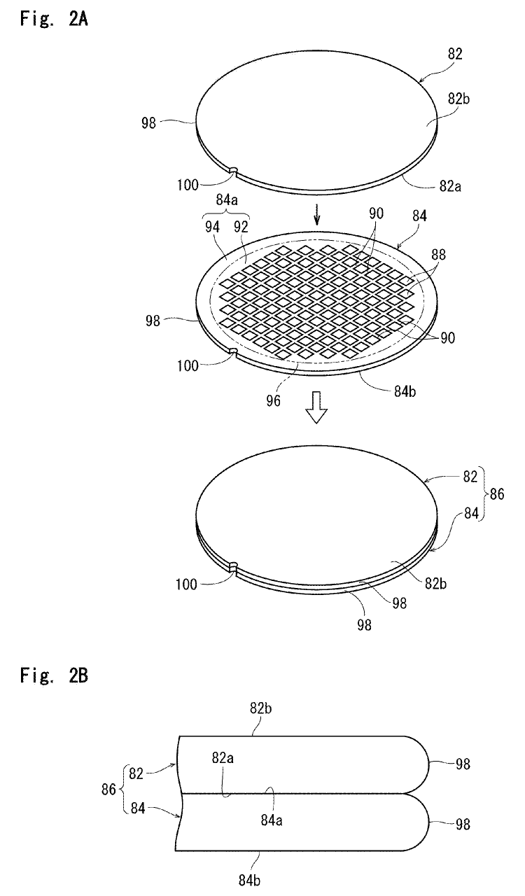

FIGS. 2A and 2B show a bonded wafer 86 in which a first wafer 82 and a second wafer 84 are bonded. The first and second wafers 82 and 84 are made of silicon (Si) and may be formed to have a diameter of 300 mm and a thickness of 775 μm, for example. The second wafer 84 has a surface 84a including a device region 92, in which multiple devices 88 such as ICs and LSIs are defined by lattice-shaped division lines 90, and an outer peripheral surplus region 94, which surrounds the device region 92. In FIG. 2A, for the sake of convenience, a ring-shaped boundary 96 between the device region 92 and the outer peripheral surplus region 94 is indicated by the dashed double-dotted line, but a line indicating the boundary 96 is not actually present. Although not shown, a surface 82a of the first wafer 82 has the same configuration as the surface 84a of the second wafer 84. As shown in FIG. 2B, the first wafer 82 and the second wafer 84 have curved chamfered portions 98 at their outer peripheries. The width of each chamfered portion 98 may be about 2 mm to 3 mm, for example. Furthermore, the outer peripheries of the first and second wafers 82 and 84 each include a notch 100 indicating the crystal orientation (see FIG. 2A).

To form the bonded wafer 86, the notch 100 of the first wafer 82 is aligned with the notch 100 of the second wafer 84, and the surface 82a of the first wafer 82 is bonded to the surface 84a of the second wafer 84. After the first wafer 82 and the second wafer 84 are bonded, heat treatment is performed to cause the first and second wafers 82 and 84 to adhere to each other via siloxane bonding. The siloxane bonding is Si-O-Si bonding in which silicon (Si) and oxygen (O) are alternately bonded, and a strong bonding state can be maintained even at high temperatures.

### Wafer Processing Method

The method for processing the first wafer 82 of the bonded wafer 86 is now described.

### Forming Modified Layer

The present embodiment first performs forming of a ring-shaped modified layer by holding the second wafer 84 of the bonded wafer 86 on the holding table and applying a laser beam with the focal point of the laser beam positioned on the inner side adjacent to the chamfered portion 98 formed at the outer periphery of the first wafer 82 of the bonded wafer 86.

### Laser Processing Apparatus 102

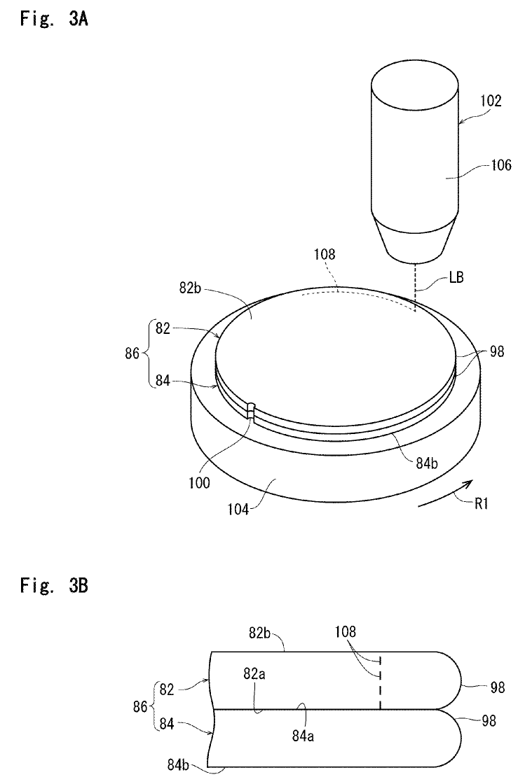

Forming of the modified layer may be performed using a laser processing apparatus 102 shown in FIG. 3A, for example. The laser processing apparatus 102 includes a holding table 104, which holds the wafer by suction, an oscillator (not shown), which emits a pulsed laser beam LB having a wavelength that is transmittable through the bonded wafer 86, and a focusing unit 106, which focuses and applies a laser beam LB emitted by the oscillator onto the first wafer 82.

In forming a modified layer, the second wafer 84 of the bonded wafer 86 is first held on the holding table 104. At this time, the bonded wafer 86 is placed on the upper surface of the holding table 104 with the back surface 84b of the second wafer 84 facing downward. Also, the center of rotation of the holding table 104 is aligned with the center of the bonded wafer 86. Then, a suction force is generated at the upper surface of the holding table 104 by a suction unit (not shown), and the back surface 84b of the second wafer 84 is held by suction on the upper surface of the holding table 104.

Once the second wafer 84 of the bonded wafer 86 is held on the holding table 104, a processing line along which the laser beam LB is to be applied is set. At this time, an imaging unit (not shown) of the laser processing apparatus 102 captures an image of the first wafer 82 from above, and the outer periphery and the center position of the first wafer 82 are detected based on the image of the first wafer 82 captured by the imaging unit. Then, based on the detected outer periphery and the center position of the first wafer 82, a ring-shaped line located on the inner side (the outer peripheral surplus region 94 or the boundary 96) adjacent to the chamfered portion 98 formed at the outer periphery of the first wafer 82 is set as the processing line.

Once the processing line to which the laser beam LB is applied is set, the focal point of the laser beam LB is positioned at a required height along the processing line. To this end, a height detection unit (not shown) of the laser processing apparatus 102 is used to detect the height of the back surface 82b of the first wafer 82 (the height of the upper surface of the bonded wafer 86). Then, using the detected height of the back surface 82b as a reference, the focal point of the laser beam LB is positioned at a required height (inside the outer peripheral surplus region 94) on the processing line.

After positioning the focal point of the laser beam LB at the required height along the processing line, the laser beam LB having a wavelength that is transmittable through the bonded wafer 86 is applied onto the first wafer 82 to form a ring-shaped modified layer 108 along the chamfered portion 98. That is, while rotating the holding table 104 at a predetermined rotational speed in the direction indicated by arrow R1 in FIG. 3A, the laser beam LB is applied to the first wafer 82, forming a ring-shaped modified layer 108 around the entire circumference of the ring-shaped processing line.

After one ring-shaped modified layer 108 (one round) is formed, the height of the focal point of the laser beam LB is shifted to a shallower position, and the laser beam LB is applied to the first wafer 82 in the same manner as above. By repeating the shifting of the focal point height and the application of the laser beam LB in this manner, multiple ring-shaped modified layers 108 are formed at intervals in the up-down direction (see FIG. 3B). The modified layers 108 adjacent to each other in the up-down direction are connected to each other by a crack (not shown) extending from the modified layers 108.

Forming of the modified layer may be performed under the following processing conditions, for example. The defocus described below is the amount of movement of the focusing unit 106 when the focusing unit 106 is moved toward the bonded wafer 86 from a state in which the focal point of the laser beam LB is positioned on the back surface 82b (exposed surface) of the first wafer 82.

Laser beam wavelength: 1099 nm to 1342 nm

Repetition frequency: 80 kHz

Rotational speed of holding table: 60 rpm

Average output: 2 W

Defocus: 650 μm, 500 μm, 350 μm, 200 μm

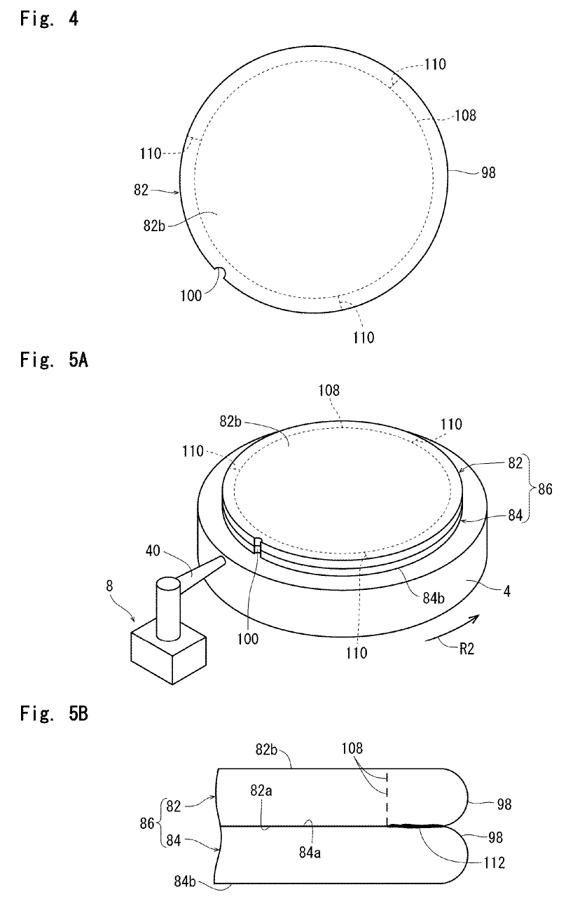

In forming the modified layer, modified layers 110 extending radially from the ring-shaped modified layer 108 may also be formed (see FIG. 4). That is, multiple (three in the present embodiment) linear modified layers 110 extending radially outward from the ring-shaped modified layer 108 to the outer periphery of the first wafer 82 may be formed. The modified layers 110 may be formed radially at equal intervals in the circumferential direction inside the first wafer 82. As with the ring-shaped modified layer 108, the radial modified layers 110 are preferably formed in multiple layers at intervals in the up-down direction. Forming such radial modified layers 110 allows the chamfered portion 98 to be divided into smaller pieces and removed in a desirable manner when performing the grinding described below.

### Loading

After forming the modified layer, loading is performed to load the bonded wafer 86 onto the grinding apparatus, which grinds the first wafer 82 of the bonded wafer 86. In this embodiment, an example is described in which the bonded wafer 86 is loaded onto the grinding apparatus 2 described above.

In loading, the first and second cassettes 42a and 42b are placed on the first and second cassette tables 44a and 44b. At this time, multiple bonded wafers 86, each having a ring-shaped modified layer 108 formed in the first wafer 82, are contained in the first cassette 42a. Then, the first cassette 42a containing the multiple bonded wafers 86 is placed on the first cassette table 44a. Also, an empty second cassette 42b for containing the bonded wafers 86 after grinding is placed on the second cassette table 44b.

After the first and second cassettes 42a and 42b are placed on the first and second cassette tables 44a and 44b, the bonded wafer 86 is loaded onto the chuck table 4 from the first cassette 42a. First, the transport unit 48 transports the bonded wafer 86 before grinding to the support base 54 of the temporary receiving table 46 from the first cassette 42a. At this time, the bonded wafer 86 is placed on the support base 54 with the first wafer 82 on the upper side and the second wafer 84 on the lower side. The multiple pins 56 of the temporary receiving table 46 are moved in synchronization so that the multiple pins 56 abut against the outer periphery of the bonded wafer 86 placed on the support base 54, thereby aligning the center of the bonded wafer 86 with the center of the support base 54. Then, the loading unit 50 loads the bonded wafer 86 onto the chuck table 4 that is positioned at the loading and unloading region A, and the bonded wafer 86 is placed on the upper surface of the chuck table 4. A suction force is then generated in the suction chuck 10 of the chuck table 4, and the chuck table 4 holds the bonded wafer 86 by suction. The loading is performed in this manner.

### Supplying Fluid

In this embodiment, the loading described above includes supplying a fluid for weakening the bonding force to the interface of the chamfered portion 98 at which the first and second wafers 82 and 84 are bonded.

The supplying of fluid in the loading may be performed after the first cassette 42a is placed on the first cassette table 44a and before transporting the bonded wafer 86 to the temporary receiving table 46 from the first cassette 42a. In this case, after the first cassette 42a is placed on the first cassette table 44a, the water tank set around the first cassette table 44a is lifted and lowered to an operating position where it can store fluid. Then, a fluid for weakening the bonding force at the interface of the chamfered portion 98 is stored in the water tank, and multiple bonded wafers 86 in the first cassette 42a are submerged. The fluid for weakening the bonding force is thus supplied to the interface of the chamfered portion 98. Subsequently, the water tank is placed at a non-operating position, the fluid is discharged from the water tank, and the bonded wafer 86 is loaded onto the chuck table 4 as described above.

Alternatively, the supplying of fluid in the loading may be performed after the bonded wafer 86 is placed on the support base 54 of the temporary receiving table 46 and before centering the bonded wafer 86. In this case, after the bonded wafer 86 is placed on the support base 54 of the temporary receiving table 46, the water tank set around the temporary receiving table 46 is lifted and lowered to be positioned at an operating position where the water tank can store the fluid. Then, a fluid for weakening the bonding force at the interface of the chamfered portion 98 is stored in the water tank, and the bonded wafer 86 on the support base 54 is submerged. The fluid for weakening the bonding force is thus supplied to the interface of the chamfered portion 98. Subsequently, the water tank is placed at a non-operating position, the fluid is discharged from the water tank, and the bonded wafer 86 is centered and then loaded onto the chuck table 4 as described above.

Furthermore, the supplying of fluid in the loading may also be performed after holding the bonded wafer 86 by suction on the chuck table 4 positioned at the loading and unloading region A. In this case, after the bonded wafer 86 is held by suction on the chuck table 4 at the loading and unloading region A, a fluid is injected toward the outer periphery of the bonded wafer 86 from the fluid supply nozzle 40 set at the loading and unloading region A, while rotating the chuck table 4 in the direction indicated by arrow R2 shown in FIG. 5A. The fluid for weakening the bonding force is thus supplied to the interface of the chamfered portion 98.

As described above, the bonded wafer 86 of the present embodiment is bonded by siloxane bonding (Si-O-Si bonding). As such, when the fluid is supplied to the chamfered portion 98, the fluid gradually enters the bonding surface from the outer periphery of the bonded wafer 86. The region into which the fluid enters changes to Si-OH-OH-Si bonding. As a result, the bonding force of the region into which the fluid enters is weakened, forming a weakened bonding force region 112 at the interface of the chamfered portion 98 (outward of the bonding surface) in a ring shape (see FIG. 5B).

### Grinding

After loading, grinding is performed to thin the first wafer 82 and remove the chamfered portion 98 formed at the outer periphery of the first wafer 82 with the force of grinding.

### Rough Grinding in Grinding

In grinding, first, the back surface 82b of the first wafer 82 is roughly ground. In the rough grinding, the turntable 12 is first rotated by 120 degrees, and the chuck table 4 holding the bonded wafer 86 by suction is moved from the loading and unloading region A to the rough processing region B. The chuck table 4 is then rotated in the direction indicated by arrow R3 in FIG. 6A at a predetermined rotational speed (for example, 300 rpm). Also, the spindle 24 of the first grinding unit 6a is rotated in the direction indicated by arrow R4 at a predetermined rotational speed (for example, 6000 rpm). Then, the spindle 24 is lowered by the first grinding feed unit 6b to bring the grindstones 34a for rough grinding into contact with the back surface 82b of the first wafer 82, and grinding water is supplied to the portion where the grindstones 34a come into contact with the back surface 82b of the first wafer 82. The spindle 24 is then lowered at a predetermined grinding feed rate (for example, 1.0 μm/s). The back surface 82b of the first wafer 82 is thus roughly ground to thin the first wafer 82. Also, the grinding force applied to the bonded wafer 86 from the first grinding unit 6a can remove the chamfered portion 98 formed at the outer periphery of the first wafer 82 (see FIGS. 6A and 6B).

In grinding, the fluid supplying may be performed when performing rough grinding. In this case, after the chuck table 4 is positioned at the rough processing region B from the loading and unloading region A and before rough grinding is performed on the back surface 82b of the first wafer 82, a fluid is injected toward the outer periphery of the bonded wafer 86 from the fluid supply nozzle 40 set at the rough processing region B, while rotating the chuck table 4. The fluid for weakening the bonding force is thus supplied to the interface of the chamfered portion 98. Alternatively, while the back surface 82b of the first wafer 82 is roughly ground, a fluid may be injected toward the outer periphery of the bonded wafer 86 from the fluid supply nozzle 40 set at the rough processing region B so as to supply the fluid for weakening the bonding force to the interface of the chamfered portion 98.

### Finish Grinding in Grinding

After roughly grinding the back surface 82b of the first wafer 82, the back surface 82b of the first wafer 82 is finish-ground. To perform finish grinding, first, the turntable 12 is rotated by 120 degrees to position the chuck table 4 holding the bonded wafer 86 by suction at the finish processing region C from the rough processing region B. The chuck table 4 is then rotated in the direction indicated by arrow R5 in FIG. 7A at a predetermined rotational speed (for example, 300 rpm). Also, the spindle 24 of the second grinding unit 6c is rotated in the direction indicated by arrow R6 at a predetermined rotational speed (for example, 6000 rpm). Then, the spindle 24 is lowered by the second grinding feed unit 6d to bring the grindstones 34b for finish grinding into contact with the back surface 82b of the first wafer 82, and grinding water is supplied to the portion where the grindstones 34b come into contact with the back surface 82b of the first wafer 82. The spindle 24 is then lowered at a predetermined grinding feed rate (for example, 0.1 μm/s). The back surface 82b of the first wafer 82 is thus finish-ground (see FIG. 7B). Subsequently, the turntable 12 is rotated by 120 degrees to position the chuck table 4 holding the bonded wafer 86 by suction at the loading and unloading region A from the finish processing region C.

### Cleaning

After grinding, cleaning of the bonded wafer 86 is performed. In cleaning, the bonded wafer 86 is first unloaded by the unloading unit 68 from the chuck table 4 positioned at the loading and unloading region A to the spinner table 78 of the cleaning unit 70. The bonded wafer 86 is then held by suction on the upper surface of the spinner table 78. Then, the bonded wafer 86 is cleaned by injecting cleaning water from the cleaning water nozzle while rotating the spinner table 78. The bonded wafer 86 is then dried by injecting dry air from an air nozzle while rotating the spinner table 78. After cleaning, the transport unit 48 transports the cleaned bonded wafer 86 to the second cassette 42b.

As described above, the present embodiment forms a ring-shaped weakened bonding force region 112 at the interface of the chamfered portion 98 by supplying a fluid for weakening the bonding force to the interface of the chamfered portion 98 at which the first and second wafers 82 and 84 are bonded. Thus, when the first wafer 82 is thinned by grinding, the chamfered portion 98 of the first wafer 82 can be easily removed. Also, since a cutting blade is not needed to remove the chamfered portion 98, the second wafer 84 is not scratched.

Although siloxane bonding has been described as an example of the bonding of the bonded wafer 86 in this embodiment, the bonding is not limited to siloxane bonding and may be SiCN bonding, TEOS bonding, or ThOx bonding, for example. Such bonding can also weaken the bonding force of the bonded wafer 86 by supplying a fluid for weakening the bonding force to the interface of the chamfered portion 98 at which the first wafer 82 and the second wafer 84 are bonded. Furthermore, the bonding force of the bonded wafer 86 can also be weakened by applying O₂ plasma or N₂ plasma as pretreatment to the bonding surface of the bonded wafer 86.

### Reference Signs List

2 Grinding apparatus

4 Chuck table

6 Grinding unit

6a First grinding unit

6b First grinding feed unit

6c Second grinding unit

6d Second grinding feed unit

8 Fluid supply unit

32 Grinding wheel

34a Grindstone for rough grinding

34b Grindstone for finish grinding

40 Fluid supply nozzle

42 Cassette

42a First cassette

42b Second cassette

44 Cassette table

44a First cassette table

44b Second cassette table

46 Temporary receiving table

48 Transport unit

50 Loading unit

82 First wafer

82a Surface of the first wafer

82b Back surface of the first wafer

84 Second wafer

84a Surface of the second wafer

84b Back surface of second wafer

86 Bonded wafer

98 Chamfered portion

108 Ring-shaped modified layer

A Loading and unloading region

B Rough processing region

C Finish processing region

What is claimed is:

1. A wafer processing method for processing a first wafer of a bonded wafer in which the first wafer and a second wafer are bonded, the wafer processing method comprising:
forming a ring-shaped modified layer by holding the second wafer of the bonded wafer on a holding table and applying a laser beam with a focal point of the laser beam positioned on an inner side adjacent to a chamfered portion formed at an outer periphery of the first wafer of the bonded wafer;
loading the bonded wafer onto a grinding apparatus for grinding the first wafer of the bonded wafer; and
grinding the first wafer to thin the first wafer and remove the chamfered portion formed at the outer periphery of the first wafer by a grinding force, wherein
the loading or the grinding includes supplying a fluid for weakening a bonding force to an interface of the chamfered portion at which the first wafer and the second wafer are bonded.

2. The wafer processing method of claim 1, wherein the supplying the fluid uses a fluid supply nozzle having a tip for injecting the fluid.

3. The wafer processing method of claim 1, wherein the fluid is water.

4. The wafer processing method of claim 1, wherein
the first wafer and the second wafer are bonded via Si-O-Si siloxane bonding, and
the supplying the fluid includes the fluid for weakening the bonding force converting Si-O-Si bonding into Si-OH-OH-Si bonding to weaken the bonding force.

5. A grinding apparatus for grinding a first wafer of a bonded wafer in which the first wafer and a second wafer are bonded, the grinding apparatus comprising:
a chuck table configured to hold the bonded wafer; a grinding unit including a grinding wheel that is rotationally attached and includes grindstones arranged annularly to grind the first wafer of the bonded wafer held by the chuck table; and a fluid supply unit configured to supply a fluid for weakening a bonding force to an interface of a chamfered portion at which the first wafer and the second wafer are bonded.

6. The grinding apparatus of claim 5, further comprising:
a cassette table on which a cassette containing a plurality of the bonded wafers is to be placed; a transport unit configured to unload the bonded wafer from the cassette placed on the cassette table and transport the bonded wafer to a temporary receiving table at which centering is performed; a loading unit configured to load the bonded wafer onto the chuck table positioned at a loading and unloading region from the temporary receiving table; and a moving unit configured to move the chuck table from the loading and unloading region to a processing region at which the grinding unit grinds the first wafer, wherein
the fluid supply unit is located at the loading and unloading region or the processing region.

7. The grinding apparatus of claim 5, wherein the fluid is water.

8. The grinding apparatus of claim 5, wherein
the first wafer and the second wafer are bonded via Si-O-Si siloxane bonding, and
the fluid for weakening the bonding force converts Si-O-Si bonding into Si-OH-OH-Si bonding to weaken the bonding force.
